(19) United States
(12) Patent Application Publication
(10) Pub. No.: US 2026/0331420 A1
(43) Pub. Date: Oct. 22, 2026

(54) CHARGED PARTICLE BEAM DRAWING METHOD AND CHARGED PARTICLE BEAM DRAWING APPARATUS

(71) Applicant: NuFlare Technology, Inc., Yokohama-shi (JP)

(72) Inventor: Koichi NAKANISHI, Yokohama-shi (JP)

(73) Assignee: NuFlare Technology, Inc., Yokohama-shi (JP)

(21) Appl. No.: 19/529,388

(22) Filed: Feb. 4, 2026

(30) Foreign Application Priority Data
Apr. 2, 2025 (JP) 2025-061286

(51) Int. Cl. H01J 37/317; H01J 37/30

(52) U.S. Cl. CPC H01J 37/3174; H01J 37/3005; H01J 2237/0266; H01J 2237/2067

(57) ABSTRACT

According to one embodiment, a charged particle beam drawing method includes: placing, on a stage, a processed substrate electrically connected to a substrate cover that includes a first grounding mechanism and a second grounding mechanism, and bringing the first grounding mechanism and the second grounding mechanism into contact with a first conductive member and a second conductive member provided on the stage, respectively; performing a ground check by measuring a resistance value between the first conductive member and the second conductive member, and determining whether the resistance value falls within a predetermined range; and in a case where an error has occurred in the ground check, performing a process of changing a position of the processed substrate and retrying the ground check.

### CROSS-REFERENCE TO RELATED APPLICATIONS

This application is based upon and claims the benefit of priority from Japanese Patent Application No. 2025-061286, filed Apr. 2, 2025, the entire contents of which are incorporated herein by reference.

### FIELD

Embodiments described herein relate generally to a charged particle beam drawing method and a charged particle beam drawing apparatus.

### BACKGROUND

A mask drawing apparatus is an apparatus that draws a desired pattern by emitting an electron beam (a charged particle beam) onto a processed substrate that includes a substrate, a light shielding film formed on the substrate, and a resist film formed on the light shielding film. Electric charge can be accumulated in the processed substrate by electron beam irradiation during a drawing process. Such accumulation of electric charge in the processed substrate during a drawing process causes bending of the trajectory of the electron beam or diffusion of the electron beam, which might result in degradation in drawing accuracy. Therefore, it is preferable that a drawing process by a mask drawing apparatus is performed in a state where a discharge path for electric charge has been prepared by connecting the processed substrate to a ground (earth) node.

As a method for connecting the processed substrate to the ground node, there is a known method of setting a conductive substrate cover on the processed substrate and electrically connecting the processed substrate and the ground node via the substrate cover. In one example, when the processed substrate having the substrate cover set thereon is placed on a stage, the substrate cover and a spring member on the stage come into contact with each other, and the substrate cover and the ground node are electrically connected via the spring member. Accordingly, electric charge accumulated in the processed substrate is discharged to the ground node via the substrate cover, and charging of the processed substrate during a drawing process can be reduced.

However, the contact resistance value between the substrate cover and the spring member might vary depending on the state of the contact point between the substrate cover and the spring member. Therefore, a pre-drawing ground check is performed to determine whether the contact resistance value between the substrate cover and the spring member falls within a predetermined range, and a drawing process can be performed. In a case where the contact resistance value does not fall within the predetermined range during the pre-drawing ground check, or in a case where an error has occurred, the job being executed by the mask drawing apparatus is suspended, for example. This results in a loss of the time required for manufacturing masks, such as the carrying time being wasted due to the suspension of the job.

### BRIEF DESCRIPTION OF THE DRAWINGS

FIG. 1 is a block diagram illustrating an example of the hardware configuration of a drawing apparatus according to a first embodiment.

FIG. 2 is a plan view illustrating an example of the configurations of a processed substrate, a stage, spring members, and a substrate cover in the drawing apparatus according to the first embodiment.

FIG. 3 is a cross-sectional view taken along the line III-III defined in FIG. 2, illustrating an example of the configurations of the processed substrate, the stage, the spring members, and the substrate cover in the drawing apparatus according to the first embodiment.

FIG. 4 is a block diagram illustrating an example configuration of a measurement circuit in the drawing apparatus according to the first embodiment.

FIG. 5 is a flowchart illustrating an example operation of the drawing apparatus according to the first embodiment.

FIG. 6 is a flowchart illustrating an example of a pre-drawing ground check to be performed by the drawing apparatus according to the first embodiment.

FIG. 7 is a plan view illustrating an example of the layout of the stage and the processed substrate in the drawing apparatus according to the first embodiment.

FIG. 8 is a plan view illustrating an example of contact portions between a spring member and the substrate cover in the drawing apparatus according to the first embodiment.

FIG. 9 is a flowchart illustrating an example of a drawing sequence to be executed by the drawing apparatus according to the first embodiment.

FIG. 10 is a plan view illustrating a first example of the effects of the pre-drawing ground check to be performed by the drawing apparatus according to the first embodiment.

FIG. 11 is a cross-sectional view illustrating a second example of the effects of the pre-drawing ground check to be performed by the drawing apparatus according to the first embodiment.

FIG. 12 is a schematic diagram illustrating specific examples of a drawing position before and after application of centrality correction by the drawing apparatus according to the first embodiment.

FIG. 13 is a flowchart illustrating an example of a pre-drawing ground check to be performed by a drawing apparatus according to a second embodiment.

FIG. 14 is a plan view illustrating an example of the layout of a stage and a processed substrate in the drawing apparatus according to the second embodiment.

FIG. 15 is a plan view illustrating an example of contact portions between a spring member and a substrate cover in the drawing apparatus according to the second embodiment.

FIG. 16 is a flowchart illustrating an example of a drawing sequence to be executed by the drawing apparatus according to the second embodiment.

FIG. 17 is a schematic diagram illustrating specific examples of a drawing position before and after application of rotation correction by the drawing apparatus according to the second embodiment.

FIG. 18 is a block diagram illustrating an example configuration of a storage device included in a drawing apparatus according to a third embodiment.

FIG. 19 is a table illustrating an example configuration of a retry count management table in the drawing apparatus according to the third embodiment.

FIG. 20 is a flowchart illustrating an example of a method of determining an initial position of a processed substrate with respect to a stage in the drawing apparatus according to the third embodiment.

### DETAILED DESCRIPTION

In general, according to one embodiment, a charged particle beam drawing method includes: placing, on a stage, a processed substrate electrically connected to a substrate cover that includes a first grounding mechanism and a second grounding mechanism, and bringing the first grounding mechanism and the second grounding mechanism into contact with a first conductive member and a second conductive member provided on the stage, respectively; performing a ground check by measuring a resistance value between the first conductive member and the second conductive member, and determining whether the resistance value falls within a predetermined range; and in a case where an error has occurred in the ground check, performing a process of changing a position of the processed substrate and retrying the ground check.

The following is a description of each embodiment, with reference to the drawings. Each embodiment presents an example of an apparatus or a method for embodying the technical idea of the invention. The drawings are schematic or conceptual, and dimensions, ratios, and the like in the respective drawings are not necessarily the same as actual ones. In the present specification, components having substantially the same functions and configurations are denoted by the same reference signs. Letters or numbers attached to the ends of reference signs are referred to by the same reference signs, and are used to distinguish between similar elements.

In the present specification, two types of horizontal directions intersecting with each other are referred to as the “X direction” and the “Y direction”. A direction perpendicular to a plane parallel to both the X direction and the Y direction is referred to as the “Z direction”. The terms “above” and “below” mean vertically above and vertically below a component, respectively. A “planar view” means viewing a component from above, for example. “Visual recognition” includes observing an object with a microscope, a camera, or the like. “Connection” refers to electrical connection, and does not exclude connection via some other element. A “mask drawing apparatus” may be referred to as a “drawing apparatus” or an “electron (charged particle) beam drawing apparatus”.

### <1> First Embodiment

A drawing apparatus 1 according to a first embodiment is designed to shift the position of a processed substrate PS having a substrate cover 100 set thereon (this position will be hereinafter referred to as the substrate position) and retry a pre-drawing ground check in a case where an error is detected during a pre-drawing ground check, and correct the drawing position based on shift amounts dx and dY with respect to a reference position for the processed substrate PS at the start of a drawing process. In the following, the drawing apparatus 1 according to the first embodiment is described in detail.

### <1-1> Configuration

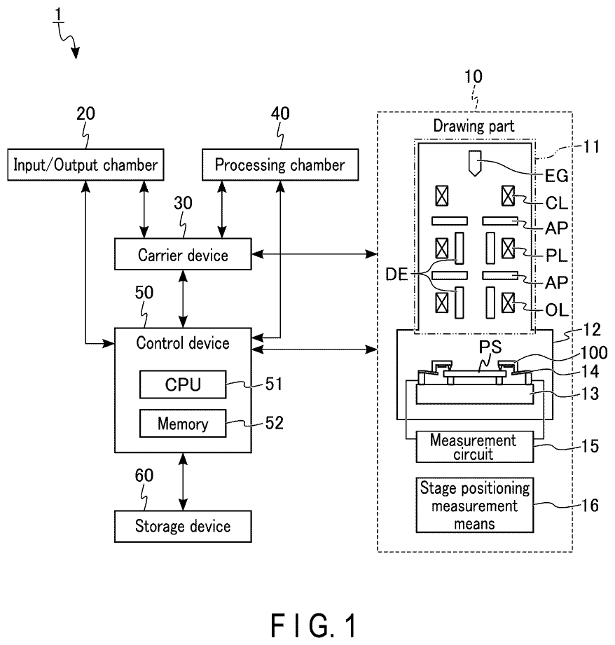

First, the configuration of the drawing apparatus 1 according to the first embodiment is described. FIG. 1 is a block diagram illustrating an example of the hardware configuration of the drawing apparatus 1 according to the first embodiment. As illustrated in FIG. 1, the drawing apparatus 1 includes a drawing part 10, a loading/unloading (input/output) chamber 20, a carrier device 30, a processing chamber 40, a control device 50, and a storage device 60, for example.

The drawing part 10 includes an electron beam irradiating means 11, a drawing chamber 12, a stage 13, a plurality of spring members 14, a measurement circuit 15, and a stage positioning measurement means 16, for example. The electron beam irradiating means 11 includes an electron gun EG, an aperture AP, a deflector DE, an illumination lens CL, a projection lens PL, an objective lens OL, and the like, and can irradiate a processed substrate PS placed on the stage 13 in the drawing chamber 12 with an electron beam, to draw a predetermined pattern on the processed substrate PS. The stage 13 is designed to be movable in an X direction parallel to the direction of progression of the drawing and in a Y direction perpendicular to the X direction in the drawing chamber 12. The processed substrate PS on which a substrate cover 100 is set can be placed on the stage 13. Each spring member 14 has conductive properties and is electrically connected to the ground node, and is designed to be contactable with the substrate cover 100 when the processed substrate PS is placed on the stage 13. The spring members 14 are leaf springs, for example. The measurement circuit 15 is electrically connected to two spring members among the plurality of spring members 14, and can measure the resistance value of the processed substrate PS through the substrate cover 100 and the two spring members. The measurement circuit 15 is then able to transfer the measurement result to the control device 50. The stage positioning measurement means 16 can measure the position of the stage 13 in the X direction and the Y direction, and is a device such as a laser positioning meter or a camera. The position of the stage 13 can be adjusted based on the result of measurement performed by the stage positioning measurement means 16.

The input/output chamber 20 is a chamber to be used for loading the processed substrate PS into the drawing apparatus 1 and unloading the processed substrate PS out of the drawing apparatus 1. The input/output chamber 20 is designed to be able to transfer the processed substrate PS to and from a coating and development device (not shown) or the like. The coating and development device is a device that performs pre-processing and post-processing for a drawing process. The pre-processing for a drawing process includes a process of applying a resist material (photosensitive material) to the processed substrate PS. The post-processing for a drawing process includes a process of developing a pattern drawn on the processed substrate PS. A plurality of kinds of semiconductor manufacturing apparatuses may be used as apparatuses to be used in pre-processing and post-processing for a drawing process.

The carrier device 30 is a device including a carrier arm capable of carrying the processed substrate PS. The carrier device 30 can carry the processed substrate PS between the input/output chamber 20 and the processing chamber 40, or between the processing chamber 40 and the drawing chamber 12, for example.

The processing chamber 40 is a chamber for performing predetermined processing before the drawing sequence described later is executed. For example, in the processing chamber 40, temperature adjustment of the processed substrate PS, positioning (alignment) of the processed substrate PS, setting of the substrate cover 100 on the processed substrate PS, and the like are executed. Note that the drawing apparatus 1 may include the following chambers separately from one another: a chamber to be used for temperature adjustment of the processed substrate PS, a chamber to be used for alignment, and a chamber to be used for setting the substrate cover 100.

The control device 50 is a computer or the like that controls the entire operation of the drawing apparatus 1, and controls each of the drawing part 10, the input/output chamber 20, the carrier device 30, the processing chamber 40, and the storage device 60. The control device 50 includes a central processing unit (CPU) 51, a memory 52, and the like. The CPU 51 is a processor that executes various programs related to the control of the drawing apparatus 1. The memory 52 is a storage medium to be used as a work area of the CPU 51. The control device 50 can perform a pre-drawing ground check based on a result of resistance value measurement performed by the measurement circuit 15. The pre-drawing ground check will be described later in detail.

The storage device 60 is a storage medium to be used for storing a control program for the drawing apparatus 1, information regarding a desired pattern to be drawn in a drawing process, and the like. The control device 50 can perform a drawing process based on the information stored in the storage device 60. The control program for the drawing apparatus 1 is loaded into the memory 52 when the drawing apparatus 1 is activated. The storage device 60 may be externally connected to the drawing apparatus 1.

(1: Configurations of the processed substrate PS, the stage 13, the spring members 14, and the substrate cover 100)

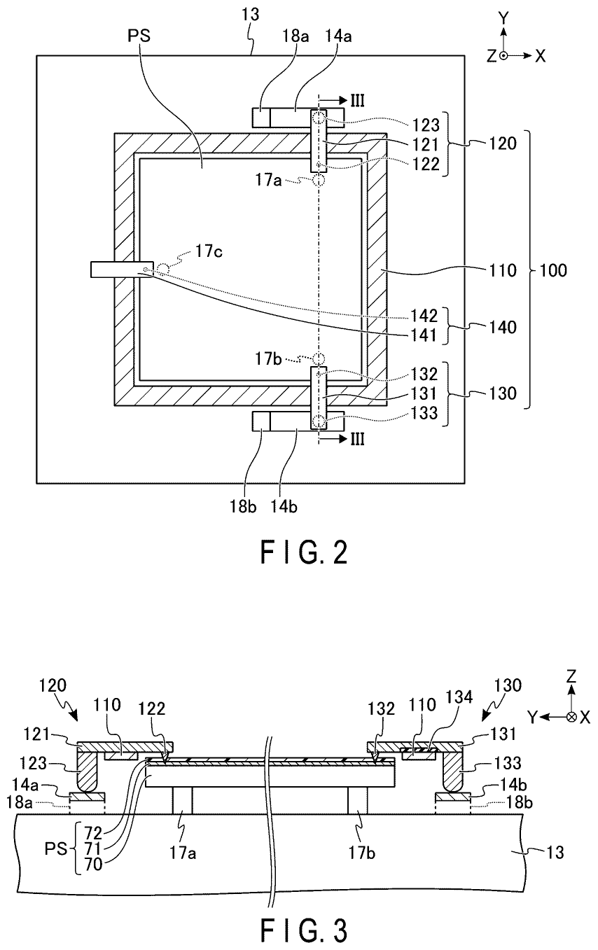

FIG. 2 is a plan view illustrating an example of the configurations of the processed substrate PS, the stage 13, the spring members 14, and the substrate cover 100 in the drawing apparatus 1 according to the first embodiment. FIG. 3 is a cross-sectional view taken along the line III-III defined in FIG. 2, illustrating an example of the configurations of the processed substrate PS, the stage 13, the spring members 14, and the substrate cover 100 in the drawing apparatus 1 according to the first embodiment. FIGS. 2 and 3 each illustrate a state in which the processed substrate PS having the substrate cover 100 set thereon is placed on the stage 13. In the following, the configuration of each of the processed substrate PS, the stage 13, the spring members 14, and the substrate cover 100 is described with reference to FIGS. 2 and 3.

The processed substrate PS includes a substrate 70, a light shielding film 71, and a resist film 72. The substrate 70 is a glass substrate, for example. The light shielding film 71 and the resist film 72 are sequentially stacked on the substrate 70. The light shielding film 71 contains chromium (Cr), for example. As the resist film 72, either a resist material (photosensitive material) of either a positive type or a negative type may be used. In a case where the processed substrate PS is placed on the stage 13, the bottom portion of the processed substrate PS (which is the bottom portion of the substrate 70) is supported by a plurality of stage pins 17a, 17b, and 17c provided on the stage 13. Note that the number of stage pins 17 is three or more, and the stage pins 17 are only required to be disposed so as to stably support the processed substrate PS.

The plurality of spring members 14 include spring members 14a and 14b. In this example, the spring members 14a and 14b are disposed so as to sandwich the processed substrate PS placed on the stage 13 in the Y direction in a planar view. In a planar view, one end of the spring member 14a in the X direction is fixed to a fixed portion 18a provided on the stage 13, and one end of the spring member 14b in the X direction is fixed by a fixed portion 18b provided on the stage 13. The spring member 14a can bend in the Z direction, with the fixed portion 18a serving as the fulcrum point, for example. The spring member 14b can bend in the Z direction, with the fixed portion 18b serving as the base point, for example. Note that the starting point from which the spring members 14a and 14b bend in the Z direction can vary depending on the strength and the like of the material forming the spring members 14.

The substrate cover 100 includes a frame 110 and a plurality of grounding mechanisms 120, 130, and 140, for example. The frame 110 has a quadrangular annular shape in a planar view, and the inner peripheral side thereof has a shape that does not overlap the drawing region of the processed substrate PS, for example. The frame 110 contains a conductive material such as titanium or zirconia. Each of the grounding mechanisms 120, 130, and 140 has a portion extending from the inner peripheral side to the outer peripheral side of the frame 110, and is fixed to the frame 110. The grounding mechanisms 120 and 130 are disposed so as to partially overlap the spring members 14a and 14b, respectively, in a case where the processed substrate PS having the substrate cover 100 set thereon is placed on the stage 13. The grounding mechanism 140 is disposed on a different side of the frame 110 from the grounding mechanisms 120 and 130, for example.

The grounding mechanism 120 includes a conductive part 121, an electrode pin 122, and a support portion 123. The conductive part 121 is provided to extend from the inner periphery to the outer periphery of the frame 110, and is electrically connected to the frame 110. The electrode pin 122 is disposed below the conductive part 121 on the inner peripheral side of the frame 110. The support portion 123 has conductive properties, and is disposed below the conductive part 121 on the outer peripheral side of the frame 110. The grounding mechanism 130 includes a conductive part 131, an electrode pin 132, a support portion 133, and an insulation portion 134. The conductive part 131 is provided to extend from the inner periphery to the outer periphery of the frame 110, and is electrically insulated from the frame 110 by the insulation portion 134. The electrode pin 132 is disposed below the conductive part 131 on the inner peripheral side of the frame 110. The support portion 133 has conductive properties, and is disposed below the conductive part 131 on the outer peripheral side of the frame 110. The grounding mechanism 140 includes a conductive part 141 and an electrode pin 142. The conductive part 141 is provided to extend from the inner periphery to the outer periphery of the frame 110, and is electrically connected to the frame 110. The electrode pin 142 is disposed below the conductive part 141 on the inner peripheral side of the frame 110.

When the substrate cover 100 is set on the processed substrate PS, each of the electrode pin 122 of the grounding mechanism 120, the electrode pin 132 of the grounding mechanism 130, and the electrode pin 142 of the grounding mechanism 140 can penetrate the resist film 72 and come into contact with the light shielding film 71. When the processed substrate PS having the substrate cover 100 set thereon is placed on the stage 13, the grounding mechanisms 120 and 130 can be supported by the spring members 14a and 14b, respectively. Thus, the light shielding film 71 of the processed substrate PS can be electrically connected to the ground node via the grounding mechanisms 120, 130, and 140. As a result, in the drawing process, the electric charge accumulated in the processed substrate PS by the irradiation with the electron beam can be discharged to the ground node via the grounding mechanisms 120, 130, and 140.

Note that, in the substrate cover 100, the grounding mechanism 140 may be omitted. In the drawing apparatus 1, a plurality of sets of the grounding mechanism 120 and the spring member 14a may be provided. The layout of the set of the spring member 14a and the grounding mechanism 120, and the layout of the set of the spring member 14b and the grounding mechanism 130 are not limited to the layouts illustrated in FIG. 2. The spring members 14a and 14b may be provided so as to be deformed depending on the pressure in the Z direction, and the location of fixing of each of the spring members 14a and 14b is not necessarily one end in the X direction, but may be one end in the Y direction. The spring members 14 may be replaced with conductive members provided to sink depending on the pressure in the Z direction. Such a conductive member can be formed with a combination of a conductive member having a substantially flat upper surface and a spring that supports the conductive member.

### (2: Configuration of the Measurement Circuit 15)

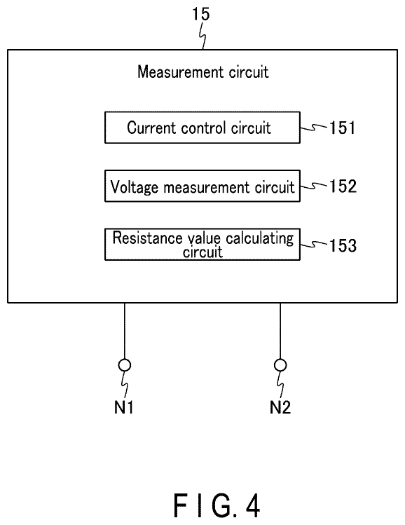

FIG. 4 is a block diagram illustrating an example configuration of the measurement circuit 15 in the drawing apparatus 1 according to the first embodiment. As illustrated in FIG. 4, the measurement circuit 15 includes a current control circuit 151, a voltage measurement circuit 152, and a resistance value calculating circuit 153, for example. The measurement circuit 15 measures a resistance value (electric resistance) between nodes N1 and N2 electrically connected to the spring members 14a and 14b, respectively, in a state where the processed substrate PS having the substrate cover 100 set thereon is placed on the stage 13. The resistance value between the nodes N1 and N2 can change depending on change in the contact resistance value between each of the spring members 14a and 14b and the substrate cover 100.

Here, a method of measuring the resistance value between the nodes N1 and N2 with the measurement circuit 15 is briefly described. First, the current control circuit 151 causes an electric current of a certain value to flow between the nodes N1 and N2. At this point of time, the current applied by the current control circuit 151 flows between the nodes N1 and N2 via the spring members 14a and 14b, the grounding mechanisms 120 and 130, and the light shielding film 71 of the processed substrate. The voltage measurement circuit 152 then measures the voltage between the nodes N1 and N2. Subsequently, the resistance value calculating circuit 153 calculates the resistance value between the nodes N1 and N2, from the value of the current flowing between the nodes N1 and N2 and the value of the measured voltage. Thus, the measurement circuit 15 can measure the resistance value via the spring members 14a and 14b, the grounding mechanisms 120 and 130, and the light shielding film 71 (this resistance value will be hereinafter referred to as the resistance value of the processed substrate PS). Note that, in a case where contact between the grounding mechanism 120 and the light shielding film 71 is poor, the grounding mechanism 140 can be used in place of the grounding mechanism 120.

### <1-2> Control Method

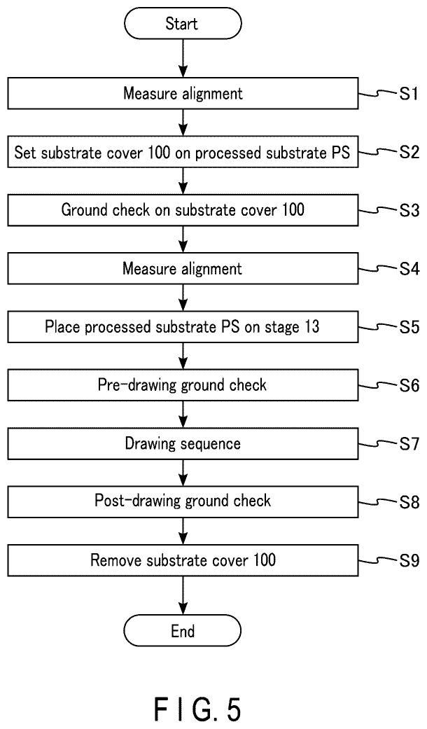

In the following, as a method for controlling the drawing apparatus 1 according to the first embodiment, an example operation of the drawing apparatus 1 is described. FIG. 5 is a flowchart illustrating an example operation of the drawing apparatus 1 according to the first embodiment. When a job is input, and the processed substrate PS is carried into the input/output chamber 20 from the outside, the control device 50 starts a series of processes illustrated in FIG. 5 (Start).

First, the processed substrate PS is carried from the input/output chamber 20 into the processing chamber 40 by the carrier device 30, and alignment measurement is performed (step S1). In the processing chamber 40, the substrate cover 100 is then set on the processed substrate PS (step S2). Subsequently, in the processing chamber 40, a ground check is conducted on the substrate cover 100 (step S3). In the ground check on the substrate cover 100 in step S3, the resistance value between the grounding mechanisms 120 and 130 is measured, and a check is made to determine whether the electrode pins 122, 132, and 142 of the substrate cover 100 set on the processed substrate PS are correctly connected to the light shielding film 71 of the processed substrate PS, for example. If an error occurs in the ground check on the substrate cover 100 in step S3, the processes in steps S2 and S3 are retried, for example. If the ground check on the substrate cover 100 in step S3 is cleared, alignment measurement is performed on the processed substrate PS having the substrate cover 100 set thereon (step S4).

When the alignment measurement on the processed substrate PS having the substrate cover 100 set thereon is completed, the processed substrate PS is placed on the stage 13 by the carrier device 30 (step S5). As a result, the processed substrate PS is supported by the stage pins 17a, 17b, and 17c on the stage 13. In the substrate cover 100, the support portion 123 of the grounding mechanism 120 is supported by the spring member 14a, and the support portion 133 of the grounding mechanism 130 is supported by the spring member 14b. Because of this, the spring members 14a and 14b are bent in the Z direction due to the weight of the substrate cover 100.

A pre-drawing ground check is then conducted (step S6), and a drawing sequence including a drawing process is executed (step S7). In the pre-drawing ground check, the electric resistance between the nodes N1 and N2 is measured, and a check is made to determine whether the processed substrate PS is connected to the ground node. In the drawing sequence, the processed substrate is irradiated with an electron beam to expose the resist film, and a desired pattern is drawn. The pre-drawing ground check and the drawing sequence in the drawing apparatus 1 according to the first embodiment will be described later in detail.

When the drawing sequence is completed, a post-drawing ground check is conducted (step S8). In the post-drawing ground check, the electrical resistance between the nodes N1 and N2 is measured as in the pre-drawing ground check, and a check is made to determine whether there is a change in the state where the processed substrate PS is connected to the ground node through the drawing process. If the post-drawing ground check is cleared, the processed substrate PS is carried into the processing chamber 40 by the carrier device 30, and the substrate cover 100 is removed from the processed substrate PS (step S9). After that, the processed substrate PS after the drawing process is carried from the input/output chamber 20 to the outside, and the series of processes illustrated in FIG. 5 is completed (End).

After post exposure bake (PEB) is performed on the processed substrate PS subjected to the drawing process, for example, a development process is performed by a coating and development device, and the resist film 72 is processed into a shape based on the pattern drawn by the drawing apparatus 1. An anisotropic etching process using the processed resist film 72 as a mask is then performed, to process the light shielding film 71 into a desired pattern. Thus, a photomask is completed.

### (1: Pre-Drawing Ground Check)

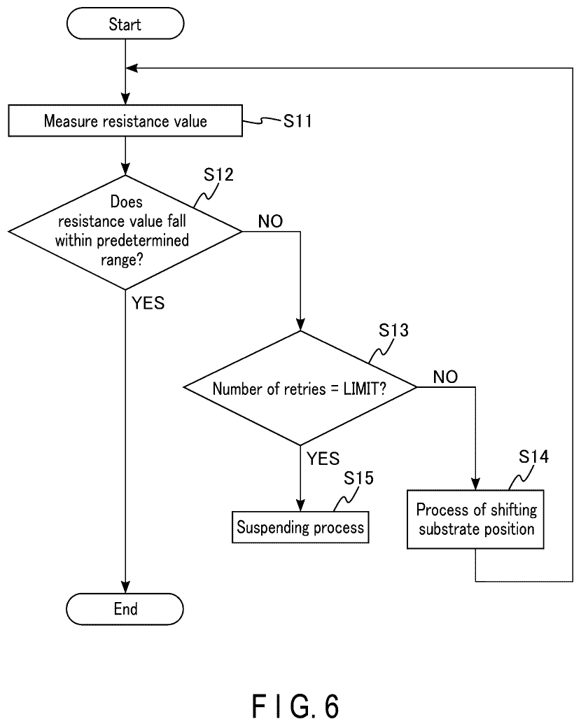

FIG. 6 is a flowchart illustrating an example of the pre-drawing ground check to be performed by the drawing apparatus 1 according to the first embodiment. In the following, the pre-drawing ground check (the process in step S6 illustrated in FIG. 5) according to the first embodiment is described in detail, with reference to FIG. 6.

When the pre-drawing ground check is started (Start), the measurement circuit 15 measures the resistance value of the processed substrate PS (step S11). The control device 50 then receives the result of the measurement of the resistance value of the processed substrate PS from the measurement circuit 15, and checks whether the resistance value of the processed substrate PS falls within a predetermined range (step S12). In other words, in the process in step S12, the control device 50 checks whether the resistance value of the processed substrate PS is not smaller than a first value and not greater than a second value. The resistance value of the processed substrate PS can vary depending on the state of the contact point between the support portion 123 of the grounding mechanism 120 of the substrate cover 100 and the spring member 14a, and the state of the contact point between the support portion 133 of the grounding mechanism 130 of the substrate cover 100 and the spring member 14b, for example. If the support portion 123 is contaminated or the spring member 14a is contaminated at the contact point between the support portion 123 and the spring member 14a, for example, the resistance value of the processed substrate PS indicates an anomalous value.

If it is confirmed in the process in step S12 that the resistance value of the processed substrate PS is not within the predetermined range, or if an error has occurred in the ground check (step S12: NO), the control device 50 checks whether “the number of retries=LIMIT” is satisfied (step S13). The number of retries corresponds to the number of times a process of changing the substrate position of the processed substrate PS placed on the stage 13 has been performed during the job being executed by the drawing apparatus 1. LIMIT is a preset parameter, and indicates the upper limit of the number of times the substrate position can be changed during the job being executed by the drawing apparatus 1.

If it is confirmed that “the number of retries=LIMIT” is not satisfied in the process in step S13 (step S13: NO), the control device 50 performs a process of shifting the substrate position (the process of changing the substrate position) (step S14). Specifically, the carrier device 30 lifts up the processed substrate PS from the stage 13, shifts the substrate position by a predetermined shift amount, and places the processed substrate PS back onto the stage 13. After that, the control device 50 proceeds to the process in step S11, again measures the resistance value of the processed substrate PS, and again performs the process in step S12. That is, the control device 50 performs a process of changing the position of the processed substrate, and retries the ground check. If “the number of retries=LIMIT” is confirmed in the process in step S13 (step S13: YES), the control device 50 performs a process of suspending the job being executed (step S15).

If it is confirmed in the process in step S12 that the resistance value of the processed substrate PS is within the predetermined range, or if it is confirmed that the ground check is cleared (step S12: YES), the control device 50 ends the series of processes illustrated in FIG. 6 (End).

Note that, at the same time as or before or after the execution of the pre-drawing ground check, the stage positioning measurement means 16 may measure the positions of the processed substrate PS placed on the stage 13 and the substrate cover 100. The positions of the processed substrate PS and the substrate cover 100 measured before the start of the drawing sequence are stored as the current position of the processed substrate PS into the memory 52 of the control device 50, for example. The control device 50 may determine whether the positions of the processed substrate PS and the substrate cover 100 are normal, in the same manner as in the pre-drawing ground check. For example, in a case where the positions of the processed substrate PS and the substrate cover 100 are anomalous, the control device 50 may perform a process of suspending the job being executed, without executing a drawing sequence.

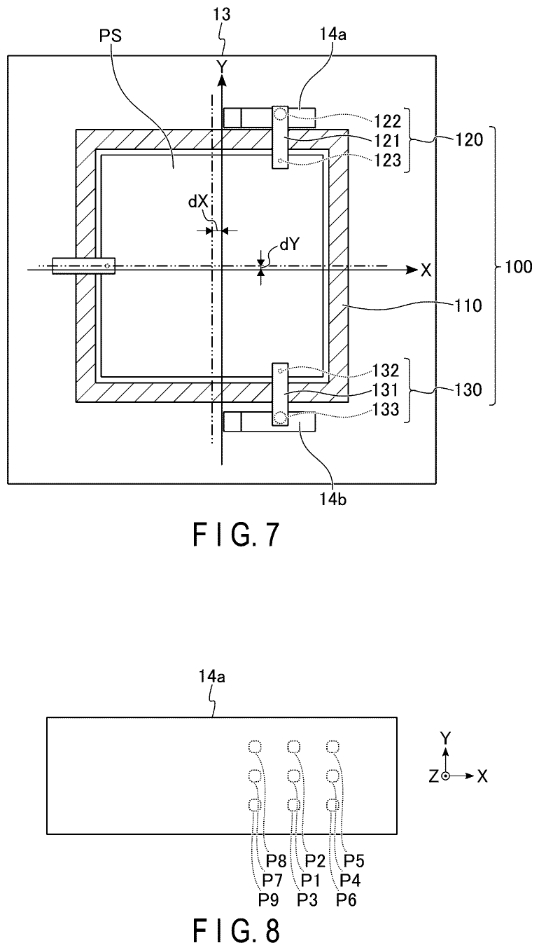

FIG. 7 is a plan view illustrating an example of the layout of the stage 13 and the processed substrate PS in the drawing apparatus 1 according to the first embodiment. The origin of the X-axis and the Y-axis shown in FIG. 7 corresponds to the mask central coordinates (hereinafter also referred to as the reference position) being uniquely managed by the drawing apparatus 1. As illustrated in FIG. 7, there are cases where the substrate position is shifted from the reference position after the pre-drawing ground check. Hereinafter, the amount of change from the reference position in the X direction will be referred to as the “shift amount dx”, and the amount of change from the reference position in the Y direction will be referred to as the “shift amount dY”. Also, the mask central coordinates (reference position) are defined as (Xo, Yo).

FIG. 8 is a plan view illustrating an example of contact portions between the spring member 14a and the substrate cover 100 in the drawing apparatus 1 according to the first embodiment. As illustrated in FIG. 8, when the processed substrate PS having the substrate cover 100 set thereon is placed on the stage 13, the control device 50 adjusts the substrate position so that the substrate cover 100 comes into contact with one of positions P1 to P9 on the spring member 14a. In the description below, it is assumed that each of the positions P1 to P9 is associated with a position of the processed substrate PS having the substrate cover 100 set thereon.

In this example, the position P1 indicates a range of a contact point between the spring member 14a and the substrate cover 100 in a case where the processed substrate PS is placed so that the center of the processed substrate PS matches the reference position. Each of the positions P2 to P9 corresponds to a position where the substrate position is shifted in the X direction from the reference position, a position where the substrate position is shifted in the Y direction, or a position where the substrate position is shifted both in the X direction and the Y direction. Specifically, positions shifted in the X direction from the reference position correspond to the positions P4 and P7, positions shifted in the Y direction from the reference position correspond to the positions P2 and P3, and positions shifted in the X direction and the Y direction from the reference position correspond to the positions P5, P6, P8, and P9. For example, the control device 50 uses the position P1 as an initial position at which the spring member 14a and the substrate cover 100 are brought into contact with each other when the processed substrate PS is placed on the stage 13. The control device 50 then changes the substrate position in the order of the positions P1 to P9, every time the process in step S14 in FIG. 6 is performed, for example. Note that the layout and the number of positions P can be set as appropriate.

### (2: Drawing Sequence)

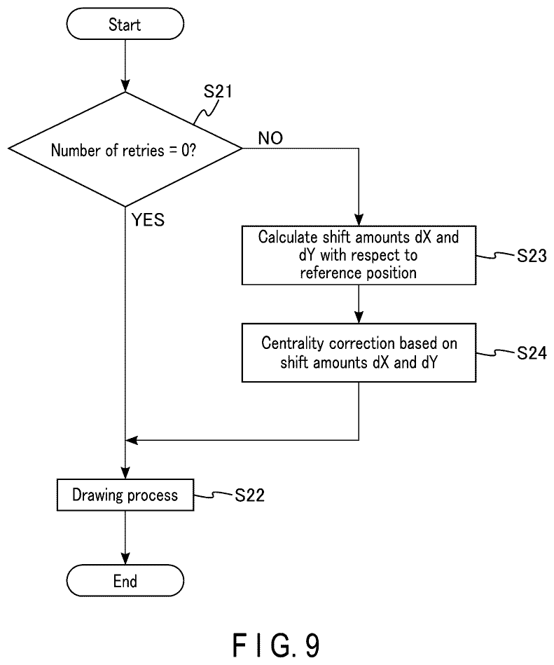

FIG. 9 is a flowchart illustrating an example of a drawing sequence to be executed by the drawing apparatus 1 according to the first embodiment. In the following, a drawing sequence (the process in step S7 shown in FIG. 5) according to the first embodiment is described in detail, with reference to FIG. 9.

When the drawing sequence starts (Start), the control device 50 checks whether the number of retries is 0 (step S21). The number of retries corresponds to the number of times a process of changing the substrate position has been performed during the job being executed by the drawing apparatus 1, as in step S13 in FIG. 6.

If it is confirmed in the process in step S21 that the number of retries is 0 (step S21: YES), the control device 50 performs a drawing process using the coordinates (Xo, Yo) of the reference position as the amount of adjustment for the central coordinates of the drawing position (step S22). During the drawing process, the light shielding film 71 of the processed substrate PS is electrically connected to the ground node via the grounding mechanisms 120, 130, and 140 of the substrate cover 100. Accordingly, when the processed substrate PS is irradiated with an electron beam during the drawing process, the electric charge accumulated in the light shielding film 71 of the processed substrate PS is discharged to the ground node via the grounding mechanisms 120, 130, and 140. Because of this, charging of the processed substrate PS during the drawing process is prevented. When the drawing of a desired pattern is completed, the control device 50 ends the series of processes illustrated in FIG. 9 (End).

On the other hand, if it is confirmed in the process in step S21 that the number of retries is not 0, or the number of retries is one or larger (step S21: NO), the control device 50 calculates the shift amounts dx and dY with respect to the reference position (step S23). The control device 50 then performs centrality correction based on the shift amounts dX and dY (step S24). The centrality correction is a process of reflecting the shift amounts dX and dY based on the number of retries of the pre-drawing ground check in the amounts of adjustment for the central coordinates of the drawing position. Specifically, the control device 50 sets the coordinates (Xo+dX, Yo+dY) of the current position as the amount of adjustment for the central coordinates of the drawing position. The control device 50 then performs a drawing process using the coordinates (Xo+dX, Yo+dY) of the current position as the amount of adjustment for the central coordinates of the drawing position (step S22). When the drawing of the desired pattern is completed, the control device 50 returns the set amount of adjustment for the central coordinates to the state before the drawing process, and ends the series of processes illustrated in FIG. 9 (End). Note that the process in step S23 may be performed before the drawing sequence.

### <1-3> Effects of the First Embodiment

With the drawing apparatus 1 according to the first embodiment described above, it is possible to prevent accumulation of electric charge in the processed substrate during a drawing process, and lower the costs for manufacturing photomasks. In the following, effects of the first embodiment are described in detail.

In the drawing apparatus 1, when the processed substrate PS having the substrate cover 100 set thereon is placed on the stage 13, the substrate cover 100 and each of the spring members 14a and 14b come into point contact with each other through a small contact area. Therefore, in a case where the contact point between the substrate cover 100 and each spring member 14 is contaminated, the contact resistance value is high, and an error might occur during the pre-drawing ground check. Further, even if the processed substrate PS is placed back on the stage 13 without a change in the substrate position, the contact position between the substrate cover 100 and each spring member 14 does not change, and an error might occur repeatedly, as long as the substrate position is not changed.

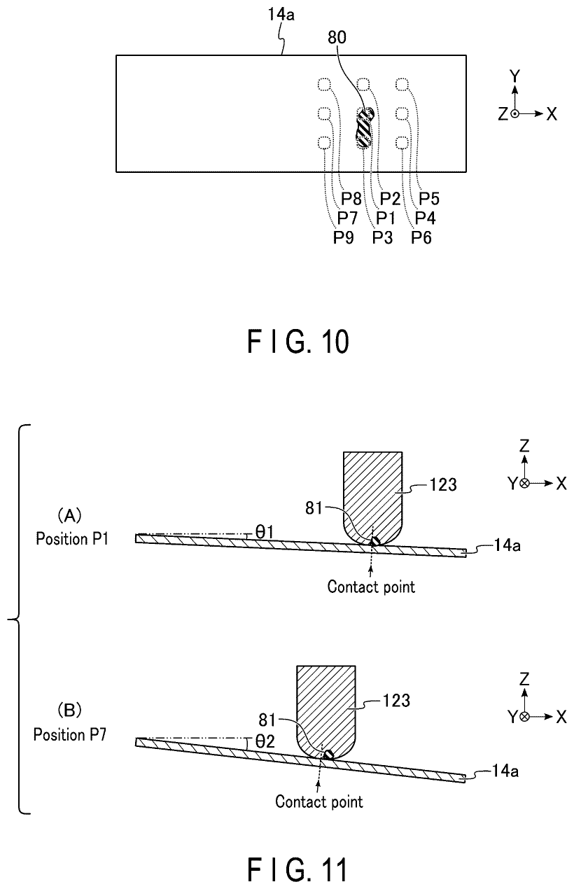

Therefore, in a case where a retry occurs during the pre-drawing ground check, the drawing apparatus 1 according to the first embodiment shifts the substrate position and changes the contact points between the substrate cover 100 and the spring members 14a and 14b. FIG. 10 is a plan view illustrating a first example of the effects of the pre-drawing ground check to be performed by the drawing apparatus 1 according to the first embodiment. FIG. 11 is a cross-sectional view illustrating a second example of the effects of the pre-drawing ground check to be performed by the drawing apparatus 1 according to the first embodiment.

As illustrated in FIG. 10, the first example illustrates a case where a contamination area 80 is formed in the spring member 14a. The contamination area 80 overlaps the position P1 at which a resistance value is first measured during the pre-drawing ground check. To counter this, the drawing apparatus 1 can avoid the overlap between the contact point and the contamination area 80 by shifting the contact point to the position P2 or the like, and increase the rate of success of the pre-drawing ground check.

As illustrated in FIG. 11, the second example illustrates a case where a contamination area 81 is formed in the support portion 123 of the grounding mechanism 120 of the substrate cover 100. In a case where the substrate position is the position P1, the contamination area 81 overlaps the contact point between the support portion 123 and the spring member 14a. To counter this, the drawing apparatus 1 can avoid the overlap between the contact point and the contamination area 81 by shifting the substrate position to the position P7 or the like, and increase the rate of success of the pre-drawing ground check. The reason for this is as follows. In a case where the processed substrate PS is placed at the position P4, the spring member 14a is bent from the horizontal level by an angle θ1. On the other hand, in a case where the processed substrate PS is placed at the position P7 shifted in the X direction (the direction in which one end of the spring member 14a is fixed by the fixed portion 18), the spring member 14a is bent from the horizontal level by an angle θ2, which is larger than θ1, and the point of contact of the support portion 123 with the spring member 14a is shifted.

As the drawing apparatus 1 according to the first embodiment shifts the substrate position at the time of a retry of the pre-drawing ground check as described above, the contact point between the substrate cover 100 and each spring member 14 can be prevented from turning into a contamination portion, and the rate of success of the pre-drawing ground check can be increased. As a result, the drawing apparatus 1 according to the first embodiment can reduce accumulation of electric charge in the processed substrate during a drawing process, and prevent an increase in the drawing time.

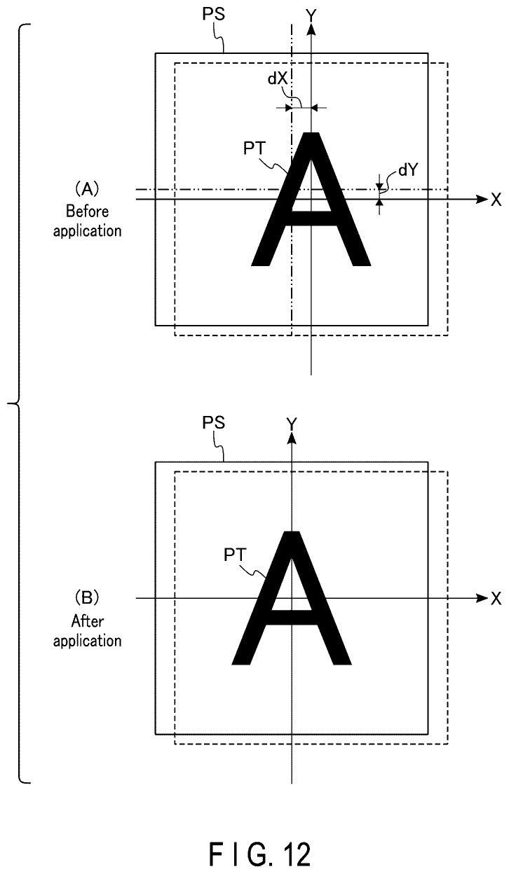

Further, in a case where the substrate position is shifted, the drawing apparatus 1 according to the first embodiment performs centrality correction based on the shift amounts dX and dY with respect to the reference position. FIG. 12 is a schematic diagram illustrating specific examples of a drawing position PT before and after application of the centrality correction by the drawing apparatus 1 according to the first embodiment. Dashed lines shown in FIG. 12 each indicate the position of the processed substrate PS before execution of the process of shifting the substrate position. (A) of FIG. 12 illustrates a state in which the central coordinates are shifted due to the execution of a change of the position of the processed substrate PS. Therefore, centrality correction is performed, so that the central coordinates are corrected as illustrated in (B) of FIG. 12. A pattern drawing position is then determined based on the corrected central coordinates, and drawing is performed.

Note that the drawing apparatus 1 according to the first embodiment may be designed to estimate a spot at which contamination has occurred depending on the direction in which the substrate position is shifted, and notify the user of the estimated spot, in a case where the substrate position has been changed in the pre-drawing ground check. For example, in a case where it is not improved by a shift from the reference position in the Y direction (the direction intersecting the direction in which one end of the spring member 14a is fixed by the fixed portion 18), there is a high possibility that one of the support portions 123 and 133 of the substrate cover 100 is contaminated. The user can check the result of the estimation of the spot at which contamination has occurred, and thus, is able to appropriately select the cleaning target. The drawing apparatus 1 may display the estimation result on a display or issue a predetermined alert as a method of reporting the estimation result.

### <2> Second Embodiment

A drawing apparatus 1 according to a second embodiment has the same configuration as that of the first embodiment, and is designed to rotate the substrate position to retry the pre-drawing ground check in a case where an error has been detected in the pre-drawing ground check, and correct the drawing position based on the rotation amount de of a processed substrate PS with respect to the reference position at the start of a drawing process. In the following, the drawing apparatus 1 according to the second embodiment is described in detail, with attention being focused mainly on differences from the first embodiment.

### <2-1> Control Method

In the following, a pre-drawing ground check and a drawing sequence are described as a method of controlling the drawing apparatus 1 according to the second embodiment.

### (1: Pre-Drawing Ground Check)

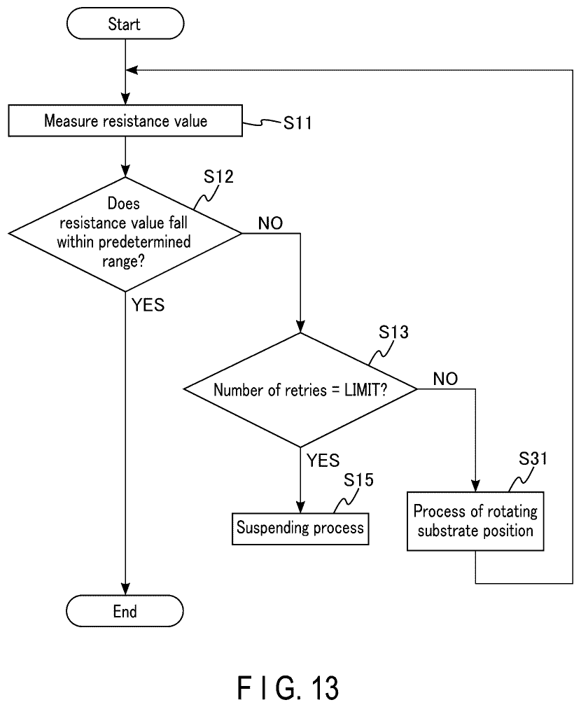

FIG. 13 is a flowchart illustrating an example of a pre-drawing ground check to be performed by the drawing apparatus 1 according to the second embodiment. In the present embodiment, a process of rotating the substrate position (step S31) is performed, instead of the process of shifting the substrate position (step S14) in the first embodiment.

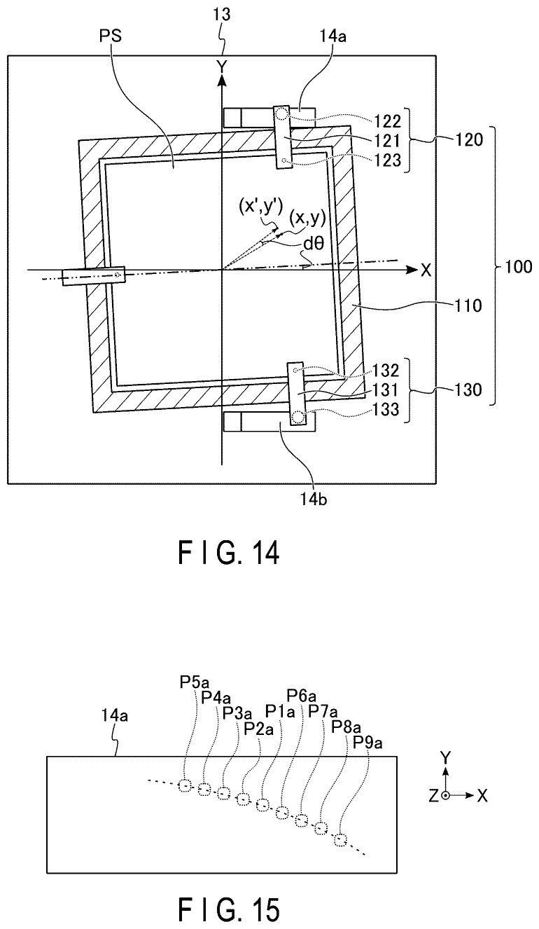

FIG. 14 is a plan view illustrating an example of the layout of a stage 13 and the processed substrate PS in the drawing apparatus 1 according to the second embodiment. The origin of the X-axis and the Y-axis shown in FIG. 14 corresponds to the mask central coordinates (reference position) being managed by the drawing apparatus 1. As illustrated in FIG. 14, there are cases where the processed substrate PS is placed on the stage 13, having been rotated about the reference position after the pre-drawing ground check. Hereinafter, the rotation amount of the processed substrate PS with respect to the reference position will be referred to as the “rotation amount de”. Further, the coordinates of the drawing position on which the rotation amount de is reflected with respect to the coordinates (x, y) of the predetermined drawing position of the processed substrate PS are shown as (x′, y′).

FIG. 15 is a plan view illustrating an example of contact portions between a spring member 14a and a substrate cover 100 in the drawing apparatus 1 according to the second embodiment. As illustrated in FIG. 15, when the processed substrate PS having the substrate cover 100 set thereon is placed on the stage 13, a control device 50 adjusts the substrate position so that the substrate cover 100 comes into contact with one of positions Pla to P9a on the spring member 14a. In the description below, it is assumed that each of the positions P1a to P9a is associated with a position of the processed substrate PS having the substrate cover 100 set thereon.

In this example, the position P1a indicates a range of a contact point between the spring member 14a and the substrate cover 100 in a case where the processed substrate PS is placed so that the center of the processed substrate PS matches the reference position. Each of the positions P2a to P9a corresponds to a position obtained by rotating the substrate position with respect to the reference position. That is, the positions P1a to P9a are arranged along a circle centered on the processed substrate PS. For example, the control device 50 uses the position P1a as an initial position at which the spring member 14a and the substrate cover 100 are brought into contact with each other when the processed substrate PS is placed on the stage 13. The control device 50 then changes the substrate position in the order of the positions P2a to P9a, every time the process in step S31 in FIG. 13 is performed, for example. Note that the layout and the number of positions P can be set as appropriate.

### (2: Drawing Sequence)

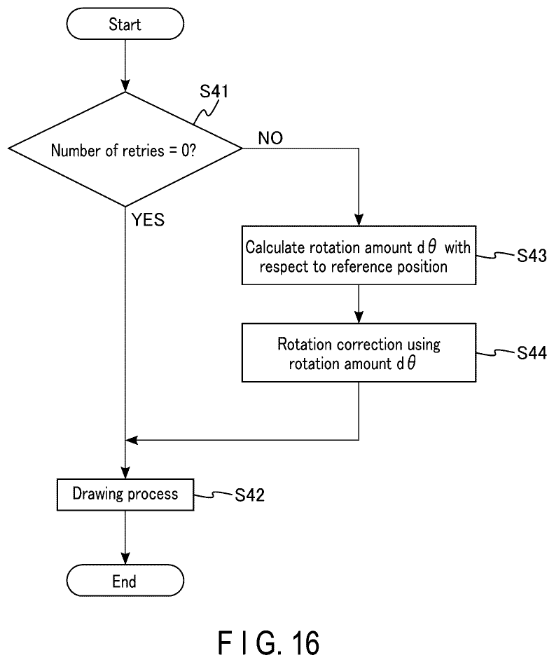

FIG. 16 is a flowchart illustrating an example of a drawing sequence to be executed by the drawing apparatus according to the second embodiment. In the present embodiment, a process of calculating the rotation amount with respect to the reference position is performed (step S43) instead of the process of calculating the shift amount with respect to the reference position (step S23) in the first embodiment, and a rotation correction process (step S44) is performed instead of the centrality correction process (step S24) based on the shift amount.

The rotation correction in step S44 in this example is a process of transferring the GMC correction amount at the coordinates (x, y) according to a grid map correction (GMC) coefficient/map, to the correction amount at the coordinates (x′, y′) after reflection of the rotation amount de. Specifically, the GMC correction amount is expressed by the sum of the GMC coefficient and the GMC map. The GMC correction amount at the coordinates (x, y) is then transferred to the coordinates (x′, y′) after reflection of the rotation amount de, based on the following Expression (1):

$$\begin{matrix}[ Mathematical Formula 1 ] & \\ ( \begin{matrix}{x}^{′} \\ {y}^{′}\end{matrix} ) = ( \begin{matrix}cos ( d θ ) & - sin ( d θ ) \\ sin ( d θ ) & cos ( d θ )\end{matrix} ) ( \begin{matrix}x \\ y\end{matrix} ) = ( \begin{matrix}x cos ( d θ ) - y sin ( d θ ) \\ x sin ( d θ ) + y cos ( d θ )\end{matrix} ) & ( 1 )\end{matrix}$$

After that, the control device 50 performs the drawing process based on the coordinates (x′, y′) after reflection of the rotation amount de (step S42). When the drawing of the desired pattern is completed, the control device 50 returns the GMC correction amount changed in the process in step S44 to the state before the drawing process, and ends the series of processes illustrated in FIG. 16 (End). The other actions of the drawing apparatus 1 according to the second embodiment are the same as those of the first embodiment. Note that the process in step S43 may be performed before the drawing sequence.

### <2-2> Effects of the Second Embodiment

In a case where a retry occurs during the pre-drawing ground check, the drawing apparatus 1 according to the second embodiment rotates the substrate position and changes the contact points between the substrate cover 100 and the spring members 14a and 14b. Because of this, the drawing apparatus 1 according to the second embodiment can prevent the contact points between the substrate cover 100 and the spring members 14a and 14b from turning into contamination areas, and increase the rate of success of the pre-drawing ground check, as in the first embodiment. As a result, the drawing apparatus 1 according to the second embodiment can prevent accumulation of electric charge in the processed substrate during a drawing process, and lower the costs for manufacturing photomasks, as in the first embodiment.

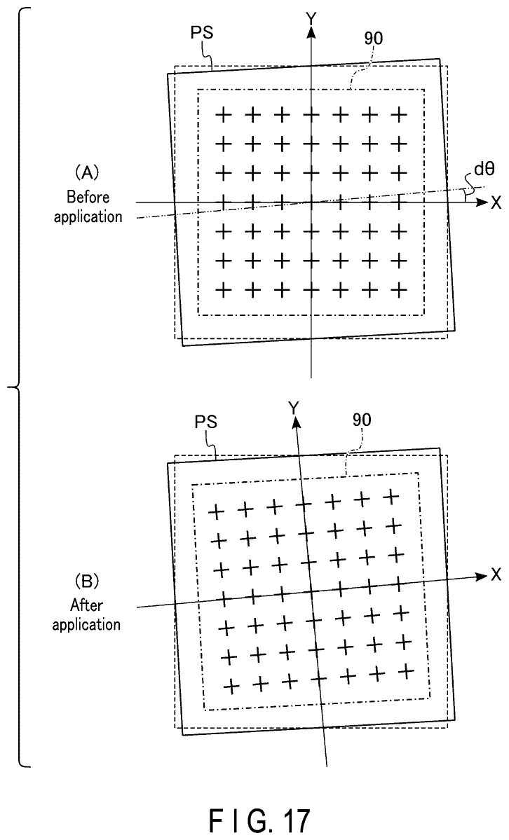

Further, in a case where the processed substrate PS is rotated, the drawing apparatus 1 according to the second embodiment performs rotation correction based on the rotation amount de with respect to the reference position. FIG. 17 is a schematic diagram illustrating specific examples of a drawing position 90 before and after application of the rotation correction by the drawing apparatus 1 according to the second embodiment. Dashed lines shown in FIG. 17 each indicate the position of the processed substrate PS before execution of the process of rotating the substrate position. (A) of FIG. 17 illustrates a state in which the drawing region is rotated due to execution of the process of rotating the substrate position. Therefore, rotation correction is performed, and drawing data is corrected so as to be aligned with the coordinate axis of the processed substrate PS, as illustrated in (B) of FIG. 17.

### <3> Third Embodiment

A drawing apparatus 1 according to a third embodiment is designed to record the number of error occurrences in the pre-drawing ground check for each position P, and determine the initial position when a processed substrate PS is placed on a stage 13 based on the number of error occurrences. In the following, the drawing apparatus 1 according to the third embodiment is described in detail, with attention being focused mainly on differences from the first and second embodiments.

### <3-1> Configuration

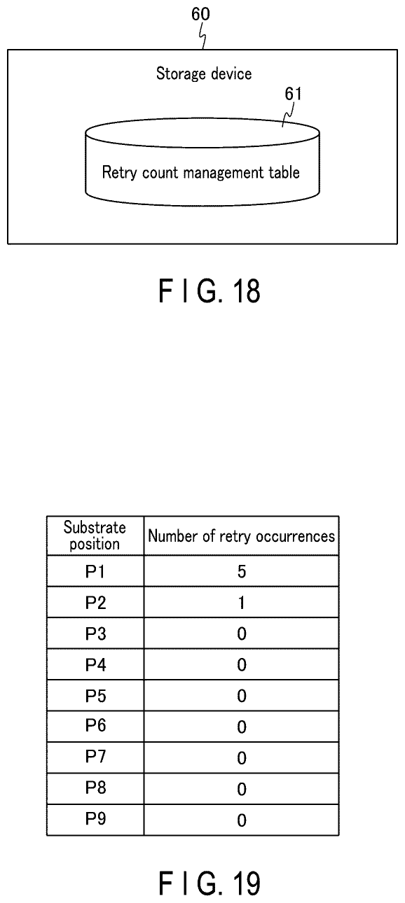

FIG. 18 is a block diagram illustrating an example configuration of a storage device 60 included in the drawing apparatus 1 according to the third embodiment. As illustrated in FIG. 18, the storage device 60 stores a retry count management table 61. The retry count management table 61 stores, for each substrate position, the number of retry occurrences accompanied by a change of the substrate position in the pre-drawing ground check. The control device 50 can update the retry count management table 61 depending on the result of the pre-drawing ground check.

FIG. 19 is a table illustrating an example configuration of the retry count management table 61 in the drawing apparatus 1 according to the third embodiment. As illustrated in FIG. 19, in the retry count management table 61, the number of retry occurrences is recorded for each position P of the processed substrate PS. In this example, five times and one time are recorded and associated with positions P1 and P2, respectively, and zero times are recorded and associated with each of positions P3 to P9. The other components of the drawing apparatus 1 according to the third embodiment are the same as those of the first embodiment.

### <3-2> Operation

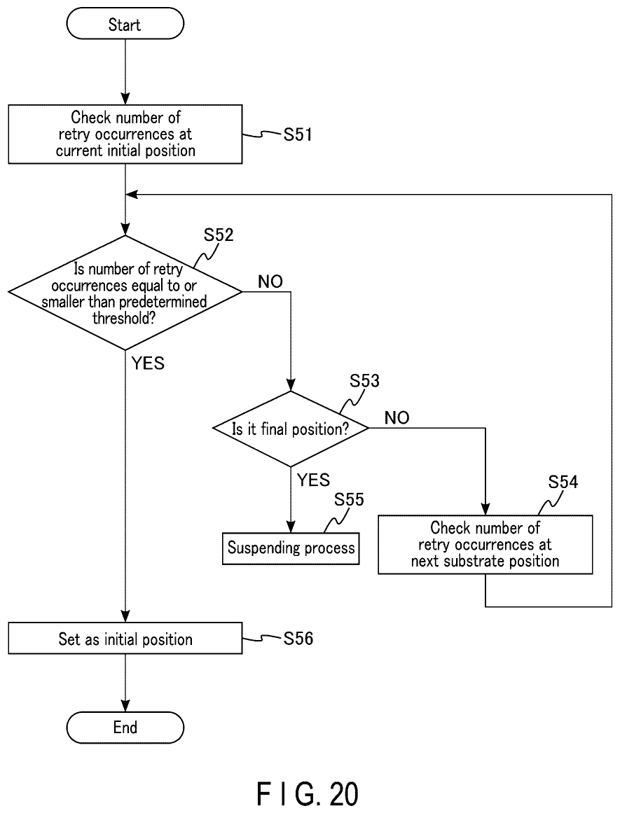

FIG. 20 is a flowchart illustrating an example of a method of determining the initial position of the processed substrate PS with respect to the stage 13 in the drawing apparatus 1 according to the third embodiment. In the following, the method of determining the initial position of the processed substrate PS in the third embodiment is described with reference to FIG. 20. The series of processes illustrated in FIG. 20 is executed before the process in step S5 shown in FIG. 5.

First, the control device 50 refers to the retry count management table 61, to check the number of retry occurrences at the current initial position (step S51). The control device 50 then checks whether the number of retry occurrences is equal to or smaller than a predetermined threshold (step S52).

If it is confirmed in the process in step S52 that the number of retry occurrences is neither equal to nor smaller than the predetermined threshold (step S52: NO), the control device 50 checks whether the position P referred to the number of retry occurrences is the final position (step S53). If it is confirmed in the process in step S53 that the position P referred to the number of retry occurrences is not the final position (step S53: NO), the control device 50 checks the number of retry occurrences at the next substrate position (step S54), and again performs the process in step S52. If it is confirmed in the process in step S53 that the position P referred to the number of retry occurrences is the final position (step S53: YES), the control device 50 performs a process of suspending the job being executed (step S55).

If it is confirmed in the process in step S52 that the number of retry occurrences is equal to or smaller than the predetermined threshold (step S52: YES), the control device 50 sets the initial position at the position P referred to the number of retry occurrences most recently (step S56), and ends the series of processes illustrated in FIG. 20.

The other actions of the drawing apparatus 1 according to the third embodiment are the same as those of the first embodiment.

Note that the predetermined threshold in step S52 may be different for each position P. In step S53, a check is made to determine whether the position P referred to the number of retry occurrences is the final position, but some other position P may be used as the determination criterion in step S53.

### <3-3> Effects of the Third Embodiment

The drawing apparatus 1 according to the third embodiment can increase the rate of success of the first pre-drawing ground check by changing the initial position of the processed substrate PS depending on the number of retry occurrences. As a result, the drawing apparatus 1 according to the third embodiment can make the costs for manufacturing photomasks lower than those with the first embodiment. Note that the drawing apparatus 1 according to the third embodiment may be designed to notify the user of the current initial position in a case where the initial position is changed. The user can examine the timing for cleaning the substrate cover 100 or each spring member 14 by checking the setting of the current initial position.

### <4> Others

Instead of the CPU 51, a micro processing unit (MPU), an application specific integrated circuit (ASIC), a field-programmable gate array (FPGA), or the like may be used as the subject that performs the processes described in the above embodiments. Each of the processes described in the above embodiments may be realized by dedicated hardware. The processes described in the above embodiments may include processes to be performed by software and processes to be performed by hardware, or may be processes to be performed only by software or processes to be performed only by hardware. In a case where the processes are to be performed by software, a program for implementing at least some of the functions of a method for controlling the drawing apparatus 1 may be stored in an external storage medium, and be read and executed by a computer. Alternatively, a program for implementing at least some of the functions of the method for controlling the drawing apparatus 1 may be distributed via a communication line such as the Internet.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A charged particle beam drawing method comprising:
placing, on a stage, a processed substrate electrically connected to a substrate cover that includes a first grounding mechanism and a second grounding mechanism, and bringing the first grounding mechanism and the second grounding mechanism into contact with a first conductive member and a second conductive member provided on the stage, respectively;
performing a ground check by measuring a resistance value between the first conductive member and the second conductive member, and determining whether the resistance value falls within a predetermined range; and
in a case where an error has occurred in the ground check, performing a process of changing a position of the processed substrate and retrying the ground check.

2. The charged particle beam drawing method according to claim 1, further comprising:
in a case where the retried ground check has been cleared, correcting a drawing position based on the changed position of the processed substrate and drawing a desired pattern on the processed substrate.

3. The charged particle beam drawing method according to claim 1, further comprising:
shifting the position of the processed substrate in at least one of a first direction parallel to a direction of progression in drawing or a second direction perpendicular to the first direction in the changing process; and,
in the correction, reflecting a shift amount corresponding to the changed position as an amount of adjustment for central coordinates of the drawing position.

4. The charged particle beam drawing method according to claim 3, further comprising:
in a case where the changing process has been performed, estimating a spot at which contamination has occurred, depending on the direction in which the position of the processed substrate is shifted.

5. The charged particle beam drawing method according to claim 1, further comprising:
rotating the processed substrate about a center position of the processed substrate in the changing process; and,
in the correction, transferring a correction amount in first coordinates to second coordinates based on a rotation amount of the processed substrate in the changing process, the second coordinates being obtained after the rotation amount is reflected on the first coordinates.

6. The charged particle beam drawing method according to claim 1, further comprising:
recording the number of retries for each position of the processed substrate; and
determining an initial position at which the processed substrate having the substrate cover set thereon is placed on the stage, based on the number of retries for each position of the processed substrate.

7. A charged particle beam drawing apparatus comprising:
a stage on which a processed substrate having a substrate cover set thereon is allowed to be placed, the substrate cover including a first grounding mechanism and a second grounding mechanism;
a first conductive member and a second conductive member that are disposed above the stage and are connectable to a ground node;
a carrier device capable of carrying the processed substrate; and
a processor configured to:
control the carrier device, to place, on the stage, the processed substrate on which the substrate cover is set, and bring the first grounding mechanism and the second grounding mechanism into contact with the first conductive member and the second conductive member, respectively;
measure a resistance value between the first conductive member and the second conductive member, and perform a ground check based on a result of measurement of the resistance value; and
in a case where an error has occurred in the ground check, perform a process of changing a position of the processed substrate and retry the ground check.
